(19) United States
(12) Patent Application Publication
(10) Pub. No.: US 2009/0039966 A1
(43) Pub. Date: Feb. 12, 2009

(54) Multi-Stage RF Amplifier Including MMICs and Discrete Transistor Amplifiers in a Single Package

(76) Inventors: Tao Chow, Los Altos Hills, CA (US); Yan Guo, San Jose, CA (US); Eric G. Casida, Sunnyvale, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 11/835,399

(22) Filed: Aug. 7, 2007

(51) Int. Cl. H03F 3/14

(52) U.S. Cl. 330/307

(57) ABSTRACT

A MMIC amplifier stage and a discrete transistor amplifier stage are housed in a single package. In one aspect, a multi-stage RF amplifier includes a package with an RF input lead and an RF output lead. The signal path from the RF input lead to the RF output lead includes one or more MMIC amplifier stages followed by one or more discrete transistor amplifier stages. Each MMIC amplifier stage includes a MMIC with at least one amplifier, and each discrete transistor amplifier stage includes at least one discrete transistor amplifier. All of the MMIC amplifier stages and discrete transistor amplifier stages are housed in the same package.

### BACKGROUND OF THE INVENTION

1. Field of the Invention

This invention relates generally to RF amplifiers, and more particularly, to RF amplifiers that use both MMICs (Monolithic Microwave Integrated Circuits) and discrete transistor amplifiers.

2. Description of the Related Art

There is an increasing utilization of RF links. With the increasing amount of networked communications and the expansion of the underlying networks, there is a corresponding increase in the number of RF links used in these networks. Point-to-point and point-to-multipoint RF links are used in ever increasing numbers and for many varying applications. The number of mobile RF nodes is also increasing as technology progresses and the demand for bandwidth increases. In addition to communications, RF links are also used for other purposes, such as radar.

Amplifiers are a basic building block for RF systems. With the growing demand for RF links, there is a corresponding demand for more and better RF amplifiers. Higher output power, higher gain, lower cost, smaller footprint, fewer parts and more flexibility are some of the goals that might apply to the development of RF amplifiers for a particular application.

As a result, technology has been developed to support the fabrication of MMICs (Monolithic Microwave Integrated Circuits). These integrated circuits allow the integration of different RF functions onto a common substrate, analogous to the development of integrated circuits for conventional digital logic. However, MMICs are still relatively difficult and/or expensive to fabricate. As a result, an RF amplifier that requires multiple stages with high power last stages can be prohibitively expensive to fabricate as a MMIC. The high power last stages typically mean a larger area MMIC. This means a more difficult fabrication and lower yield which, in turn, results in a more expensive device. In addition, thinning a MMIC for better heat transfer is often not possible because circuit elements such as inductors or higher impedance microstrip lines cannot function on a thin substrate. MMICs can also sometimes be less efficient than their discrete counterparts.

Discrete components, such as discrete power amplifiers, can overcome some of the drawbacks of MMICs. For example, a single discrete device, even if large in area, typically will have a higher yield and lower cost than a MMIC that combines several such large devices. A discrete device can also be thinned to improve heat transfer. In addition, the careful design of RF circuits using discrete components can sometimes yield better-optimized circuits. However, these advantages are at the expense of a higher part count and higher assembly cost.

In addition, cascading multiple microwave amplifiers in separate packages can result in degraded performance due to multiple transitions into and out of the packages. These transitions can introduce signal loss due to radiation or mismatch loss due to reflections from impedance discontinuities. Cascading multiple amplifiers in one package can eliminate these problems as well as reduce package cost and final assembly and tuning cost. Multiple stages result in higher gain. This requires a package that provides sufficient isolation between stages to prevent instability of the amplifier chain due to radiative coupling inside the package. Using one package instead of multiple standard packages also preferably requires a package that is easily customizable to different configurations.

As a result, there is a need for improved RF amplifiers.

### SUMMARY OF THE INVENTION

The present invention overcomes the limitations of the prior art by incorporating both a MMIC amplifier stage and a discrete transistor amplifier stage in a single package. In one aspect, a multi-stage RF amplifier includes a package with an RF input lead and an RF output lead. The signal path from the RF input lead to the RF output lead includes one or more MMIC amplifier stages followed by one or more discrete transistor amplifier stages. Each MMIC amplifier stage includes a MMIC with at least one amplifier, and each discrete transistor amplifier stage includes at least one discrete transistor amplifier. All of the MMIC amplifier stages and discrete transistor amplifier stages are housed in the same package. In one approach, all of the MMICs and all of the discrete transistor amplifiers are attached directly to the package (as opposed to attached to carriers, which are then attached to the package).

In one embodiment of the invention, the package base and walls are machined out of a single piece of material. Internal walls can also be present, separating the inside of the package into individual cavities joined by small openings. The walls provide isolation between each cavity and additional support and sealing area for the lid of the package.

In one particular design, the last discrete transistor amplifier stage includes a power divider, a power combiner, and two or more discrete transistor amplifiers coupled in parallel between the power divider and the power combiner. Lange couplers can be used as the power divider and the power combiner.

In another aspect of the invention, the multi-stage RF amplifier also includes a drain bias network, a gate bias network, an input matching network and/or an output matching network for each of the discrete transistor amplifiers. All of these additional components are also housed inside the same package. In one design, the package further includes drain bias lead(s) that couple to the drain bias network(s). In another aspect, the multi-stage RF amplifier further includes a voltage divider network that receives a voltage and divides it down to a gate bias voltage, which is then applied to the gate bias network. The voltage divider network(s) are also housed inside the package. Alternate embodiments using bipolar transistors can be constructed by replacing the “drain,” “gate” and “source” with a “collector,” “base,” and “emitter,” respectively.

Other aspects of the invention include systems using the amplifiers described above, and methods corresponding to these systems and amplifiers.

### BRIEF DESCRIPTION OF THE DRAWINGS

The invention has other advantages and features which will be more readily apparent from the following detailed description of the invention and the appended claims, when taken in conjunction with the accompanying drawings, in which:

FIG. 1 is a block diagram of an example multi-stage RF amplifier according to the invention.

FIG. 2A is a top view of a physical implementation of the multi-stage RF amplifier of FIG. 1.

FIG. 2B is a top view and side view of another physical implementation of the multi-stage RF amplifier of FIG. 1.

FIG. 3 shows a top view, side and front view of an assembled package containing the multi-stage RF amplifier of FIGS. 1 and 2.

The figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION OF THE PREFERRED EMBODIMENTS

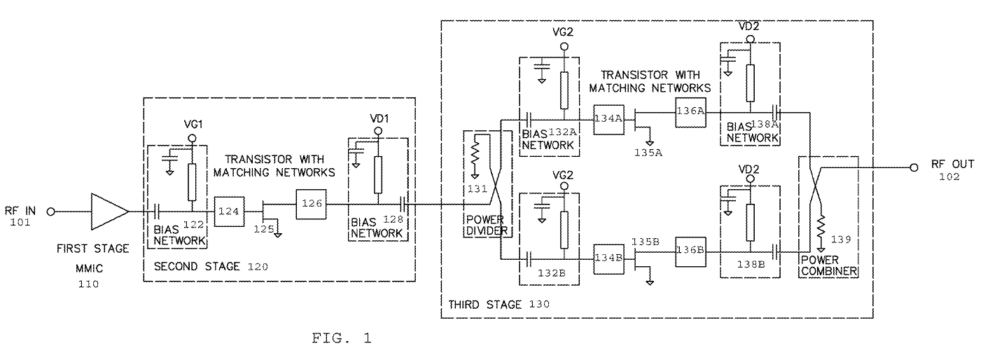

FIG. 1 is a block diagram of an example multi-stage RF amplifier according to the invention. This example includes an RF input lead 101, an RF output lead 102, and three amplifier stages 110, 120, 130 coupled between the input lead 101 and output lead 102. The first amplifier stage 110 is a MMIC amplifier stage. The second and third stages 120, 130 are discrete transistor amplifier stages.

The MMIC amplifier stage 110 is a single MMIC that includes at least one amplifier. In this particular case, the MMIC 110 contains a multi-stage amplifier—specifically, a two-stage amplifier. The MMIC 110 in this example also includes additional circuitry, for example the bias networks and matching networks for the multi-stage amplifier. One advantage of using a MMIC is that multiple types of circuitry can be included on a single integrated circuit. This results in less area required, compared to the equivalent circuit using discrete components. It also saves on assembly time and cost since there are no separate components that must be connected to each other.

In contrast, the discrete transistor amplifier stages 120, 130 are based on discrete transistors 125 and 135A-B, respectively, and additional discrete components. While this may require more area and assembly, the discrete approach can provide more flexibility (since each of the discrete components can be individually designed and/or adjusted), greater power outputs, and higher semiconductor fabrication yields (since higher power MMICs are larger and, correspondingly, have lower yields).

In more detail, the second stage 120 includes one discrete transistor amplifier 125, along with its associated bias networks 122, 128 and matching networks 124, 126. Gate bias network 122 provides biasing of the gate for transistor 125 where VG1 is the gate bias voltage; input matching network 124 provides impedance matching for the input (gate) to transistor 125. Drain bias network 128 provide biasing of the drain for transistor 125 where VD1 is the drain bias voltage; output matching network 126 provides impedance matching for the output (drain) of transistor 125. The source for transistor 125 is tied to ground.

The third stage 130 is constructed similarly, except that two transistor amplifiers 135A-B are used in parallel. A power divider 131 divides the incoming signal into two parallel signal paths, each of which is amplified by its respective amplifier 135A or 135B. The amplified signals are recombined by power combiner 139, the output of which is coupled to the RF output lead 102. Each of the signals paths A and B are similar in construction to the signal path of the second stage, including a gate bias network 132A-B with gate bias voltage VG2, input matching network 134A-B, amplifier 135A-B, output matching network 136A-B, and drain bias network 138A-B with drain bias voltage VD2. In this example, the power divider 131 and power combiner 139 are implemented as Lange couplers.

The parallel construction of the third stage 130 has several advantages (at the cost of added complexity). First, the use of multiple amplifiers in parallel can yield greater power outputs. Second, the use of several smaller amplifiers instead of one large amplifier relaxes the requirements on the amplifier and also reduces the thermal load produced by each amplifier. Finally, the Lange couplers 131, 139, by virtue of their design, provide good impedance matching and good isolation, both to the second stage 120 and to the load coupled to the RF output 102.

In this particular example, each of the individually numbered elements in FIG. 1 is implemented as a separate component. The first stage MMIC 110 is a single chip. Each of the transistors 125, 135A and 135B is implemented as a discrete component. Each of the bias networks, matching networks and power divider and power combiner is also implemented as a separate discrete component. In this particular design, the MMIC 110 is a GaAs MMIC, and each of the transistors 125, 135A-B is a GaAs MESFET. The remaining components are based on metallized ceramic substrates, sometimes with additional components attached (e.g., capacitors). The different components are coupled to each other by wires.

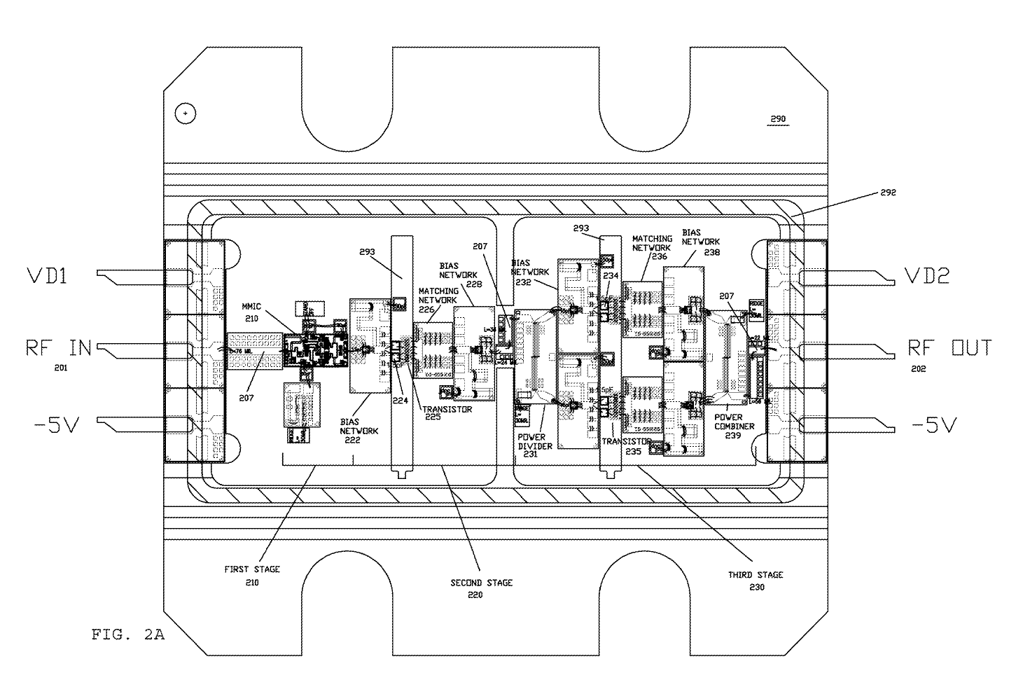

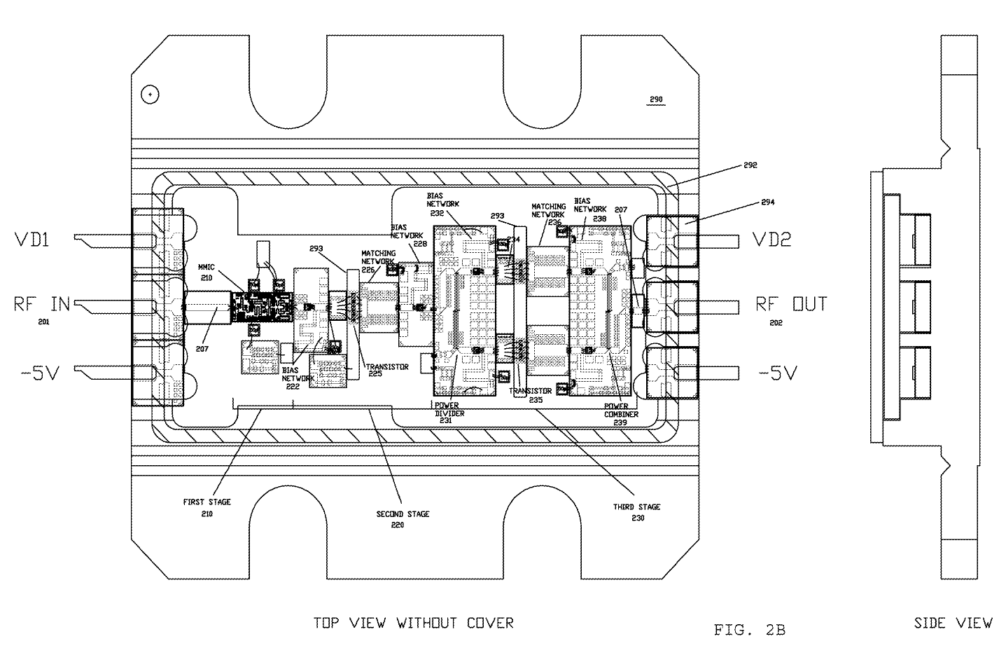

FIGS. 2A and 2B are top views of two example physical implementations of the multi-stage RF amplifier of FIG. 1. FIG. 2B also shows a side view. The top view shows the components in the package 290, but with the top of the package removed so that the components are visible. Elements with the same last two digits in FIGS. 1 and 2 correspond to each other. Thus, element 201 in FIG. 2 is the physical implementation of element 101 in FIG. 1, and so on. In addition, some of the less important features have been omitted for clarity. For example, the wire connections from leads VD1, VD2 and −5V have been omitted.

This particular package 290 is gold-plated copper for good thermal management. The various electronic components are attached directly to the gold-plated floor of the package (as opposed to attached to carriers, which are then attached to the package). This increases the thermal heat transfer from the components. The transistors 225 and 235A-B are also thinned to further reduce their thermal resistance and directly attached to copper heat spreaders 293 which are in turn directly attached to the package.

This particular example includes six leads: RF IN 201, RF OUT 202, VD1, VD2, and −5V (two leads). RF IN 201 and RF OUT 202 are the signal input and output leads. The VD1 and VD2 leads in FIG. 2 are drain bias leads for applying the bias voltages VD1 and VD2 of FIG. 1. The −5V leads receive −5V. This is applied to voltage divider networks (not shown in FIG. 2 for clarity), which convert the −5V to the appropriate gate bias voltages VG1 and VG2 for the second 220 and third stages 230, respectively.

In the example of FIG. 2B, the six leads pass through the external wall of the package with ceramic feedthroughs 254. Each ceramic feedthrough is comprised of two ceramic substrates. The bottom substrate is metallized with a pattern to form a microstrip transmission line extending from the outer edge of the package to the inside of the package. The lead is attached to top of the microstrip at the outer end of the substrate. A second substrate is attached across the center of the first substrate. Each of the feedthroughs are positioned in a separate opening in the housing wall and surrounded by metal on four sides to prevent coupling between feedthroughs.

Referring to FIG. 2, working from RF IN 201 to RF OUT 202, the signal path is as follows. RF IN 201 is coupled to the first stage 210 via microstrip line 207. The first stage 210 is a MMIC amplifier stage based on MMIC 210.

MMIC 210 is coupled to the second stage 220. The second stage 220 is a discrete transistor amplifier stage that includes gate bias network 222, input matching network 224, transistor 225, output matching network 226 and drain bias network 228.

The second stage 220 is coupled to third stage 230. The third stage 230 is a discrete transistor amplifier stage that uses the parallel amplifier approach shown in FIG. 1. The third stage 230 includes Lange coupler 231 used as a power divider and another Lange coupler 239 used as a power combiner. Each of the two parallel signal paths includes a gate bias network 232, input matching network 234, transistor 235, output matching network 236 and drain bias network 238. Various microstrip lines 207 are used throughout.

Cross-hatched region 292 is the exterior wall of the package 290. All of the components for stages 210, 220 and 230 are housed inside the package. This is advantageous because only a single package is used. This is in contrast to designs that use one package for each MMIC and one package for each discrete transistor amplifier. In addition, in these multi-package designs, additional circuitry such as the matching networks, bias networks and power dividers/combiners may be implemented outside the amplifier packages. In the design shown in FIG. 2, all of these components are contained in the same package. This reduces the area required and can also simplify the user's tasks, as the user need only supply the various bias voltages and RF signals. He need not design couplings between stages or any of the supporting circuitry (such as bias networks and matching networks).

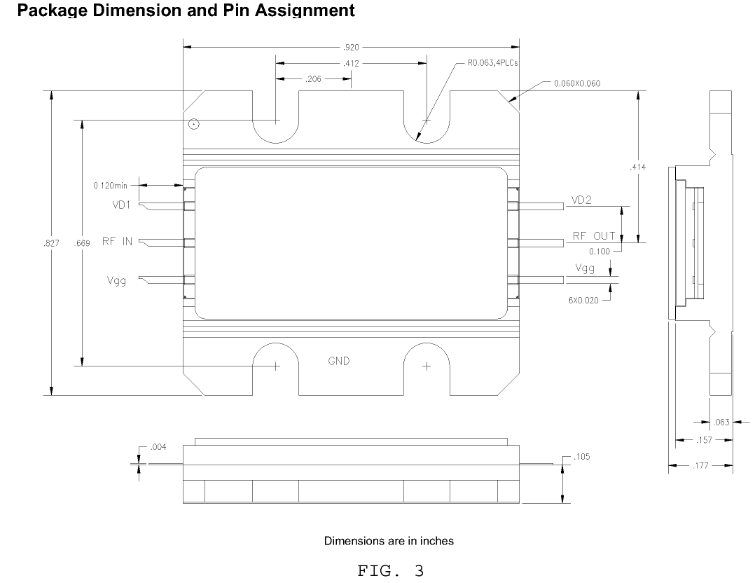

FIG. 3 shows a top view, side and front view of the assembled package for FIG. 2A. The base and walls of the package (including the internal walls restricting the width of the cavity between the second stage 220 and the third stage 230) are machined out of one piece of material. This allows different custom configurations to be easily fabricated with CNC machining. This particular package is non-hermetic. As a result, the package (including the feed-throughs for the leads) can be assembled before, during or after placement of the components inside the package. This flexibility can simplify the overall assembly process. The feedthroughs can be fabricated with the same thin film technology as the internal circuits allowing them to be customized easily and with minimal cost.

Although the detailed description contains many specifics, these should not be construed as limiting the scope of the invention but merely as illustrating different examples and aspects of the invention. It should be appreciated that the scope of the invention includes other embodiments not discussed in detail above. For example, the invention is not limited to the number of stages or the specific design for stages shown in FIG. 1. In alternate embodiments, a multi-stage RF amplifier may contain only a single MMIC amplifier stage followed by a single discrete transistor amplifier stage. The parallel design for amplifier stage 130 need not be used. In addition, materials other than GaAs can be used. GaN, SiC, Si and SiGe are examples of other suitable materials systems. In addition, the amplifiers do not have to be MESFETs (Metal-Semiconductor Field Effect Transistor). Other types of FETs, HBTs (heterojunction bipolar transistors), HEMTs (High Electron Mobility Transistor) including PHEMTs (pseudomorphic HEMTs) and MHEMTs (metamorphic HEMTs) are examples of other amplifier designs that could also be used. Other packages, including hermetic packages, could also be used. As a final example, the example given above is designed for operation in the 10.7-11.7 GHz band, but other RF bands can also be addressed. A multi-stage RF amplifier typically will be designed to operate within a 500 MHz-1 GHz wide band somewhere within the 2-20 GHz frequency range, although the invention is not limited to either of these. Typical applications include microwave digital radio and radar. Various other modifications, changes and variations which will be apparent to those skilled in the art may be made in the arrangement, operation and details of the method and apparatus of the present invention disclosed herein without departing from the spirit and scope of the invention as defined in the appended claims. Therefore, the scope of the invention should be determined by the appended claims and their legal equivalents.

In the claims, if an element is first introduced as “one or more,” a later reference to that element in the plural is not intended to mean “two or more” unless explicitly stated but rather is meant to mean “one or more.” For example, where the phrase “one or more amplifier stages” is first introduced in a claim, the later phrase “the amplifier stages” is intended to mean “the one or more amplifier stages” unless explicitly stated to the contrary. In addition, the term “coupling” is meant to include both direct and indirect coupling between two components. That is, there may be intervening elements. For example, when two elements are described as being coupled to each other, this does not imply that the elements must be directly coupled to each other nor does it preclude the use of other elements between the two.

What is claimed is:

1. A multi-stage RF amplifier comprising:
a package including an RF input lead and an RF output lead;
one or more MMIC amplifier stages, each MMIC amplifier stage including a MMIC with at least one amplifier, the first of the MMIC amplifier stages coupled to the RF input lead; and
one or more discrete transistor amplifier stages, each discrete transistor amplifier stage including at least one discrete transistor amplifier, the first of the discrete transistor amplifier stages coupled to the last of the MMIC amplifier stages, and the last of the discrete transistor amplifier stages coupled to the RF output lead;
wherein the MMIC amplifier stages and the discrete transistor amplifier stages are housed in the package.

2. The multi-stage RF amplifier of claim 1 wherein the package is a non-hermetic package.

3. The multi-stage RF amplifier of claim 1 wherein the package includes a base and external walls machined from one piece of material.

4. The multi-stage RF amplifier of claim 3 wherein the package further includes one or more internal walls machined from the same piece of material as the base and external walls.

5. The multi-stage RF amplifier of claim 1 wherein the package includes one or more ceramic feedthroughs.

6. The multi-stage RF amplifier of claim 1 wherein the one or more discrete transistor amplifier stages comprise at least two discrete transistor amplifier stages.

7. The multi-stage RF amplifier of claim 1 wherein the last of the discrete transistor amplifier stages comprises:
a power divider;
a power combiner; and
two or more discrete transistor amplifiers coupled in parallel between the power divider and the power combiner.

8. The multi-stage RF amplifier of claim 1 wherein the last of the discrete transistor amplifier stages comprises:
a first Lange coupler operating as a power divider;
a second Lange coupler operating as a power combiner; and
two discrete transistor amplifiers coupled in parallel between the first Lange coupler and the second Lange coupler.

9. The multi-stage RF amplifier of claim 1 wherein each discrete transistor amplifier stage further includes a drain bias network and an output matching network for each of the discrete transistor amplifiers in the discrete transistor amplifier stage, the drain bias network for biasing a drain of the discrete transistor amplifier and the output matching network coupled to an output of the discrete transistor amplifier; and all of the drain bias networks and output matching networks are housed in the package.

10. The multi-stage RF amplifier of claim 9 wherein the package further includes one or more drain bias leads coupled to the one or more drain bias networks.

11. The multi-stage RF amplifier of claim 9 wherein:
each discrete transistor amplifier stage further includes a gate bias network and an input matching network for each of the discrete transistor amplifiers in the discrete transistor amplifier stage, the gate bias network for biasing a gate of the discrete transistor amplifier and the input matching network coupled to an input of the discrete transistor amplifier; and
all of the gate bias networks and input matching networks are housed in the package.

12. The multi-stage RF amplifier of claim 9 wherein each discrete transistor amplifier stage further includes a voltage divider network for each of the discrete transistor amplifiers in the discrete transistor amplifier stage, the voltage divider network for biasing a gate of the discrete transistor amplifier; and all of the voltage divider networks are housed in the package.

13. The multi-stage RF amplifier of claim 1 wherein the one or more MMIC amplifier stages consists of exactly one MMIC containing a multi-stage amplifier.

14. The multi-stage RF amplifier of claim 1 wherein all of the discrete transistor amplifiers are thinned to a thickness less than that of any of the MMICs.

15. The multi-stage RF amplifier of claim 1 wherein all of the MMICs and all of the discrete transistor amplifiers are attached directly to a base of the package.

16. The multi-stage RF amplifier of claim 1 wherein the discrete transistor amplifiers are attached directly to heat spreaders that are attached directly to a base of the package.

17. The multi-stage RF amplifier of claim 1 wherein the MMICs and the discrete transistor amplifiers are all GaAs circuits.

18. The multi-stage RF amplifier of claim 1 wherein the discrete transistor amplifiers are all FETs.

19. The multi-stage RF amplifier of claim 1 wherein the discrete transistor amplifiers are all MESFETs.

20. The multi-stage RF amplifier of claim 1 wherein the discrete transistor amplifiers are all HBTs.

21. The multi-stage RF amplifier of claim 1 wherein the discrete transistor amplifiers are all PHEMTs.

22. The multi-stage RF amplifier of claim 1 wherein the discrete transistor amplifiers are all MHEMTs.

23. The multi-stage RF amplifier of claim 1 wherein the multi-stage RF amplifier is operable over a band of at least 500 MHz located in the 0-20 GHz range.
